(19) United States
(12) Patent Application Publication
(10) Pub. No.: US 2014/0054072 A1
(43) Pub. Date: Feb. 27, 2014

(54) PRINTED CIRCUIT BOARD AND METHOD FOR MANUFACTURING THE SAME

(71) Applicant: SAMSUNG ELECTRO-MECHANICS CO., LTD., Suwon (KR)

(72) Inventors: Kwang Jik LEE, Suwon (KR); Sang Hyun Shin, Suwon (KR); Hye Suk Shin, Suwon (KR); Joon Seok Kang, Suwon (KR)

(73) Assignee: Samsung Electro-Mechanics Co., Ltd., Suwon (KR)

(21) Appl. No.: 13/800,715

(22) Filed: Mar. 13, 2013

(30) Foreign Application Priority Data
Aug. 21, 2012 (KR) 10-2012-0091179

(51) Int. Cl. H05K 1/05

(52) U.S. Cl. CPC H05K 1/05
USPC 174/255; 216/13

(57) ABSTRACT

Disclosed herein are a printed circuit board and a method for manufacturing the same. The printed circuit board includes: a base substrate; an Insulating layer formed on one surface or both surfaces of the base substrate; an electrode layer formed on a top surface of the insulating layer; and an insulating film covering a surface of the insulating layer except for a bonding surface between the electrode layer and the insulating layer so as to secure high dielectric breakdown voltage while keeping high thermal conductivity.

### CROSS REFERENCE(S) TO RELATED APPLICATIONS

This application claims the benefit under 35 U.S.C. Section 119 of Korean Patent Application Serial No. 10-2012-0091179 entitled “Printed Circuit Board And Method For Manufacturing The Same” filed on Aug. 21, 2012, which is hereby incorporated by reference in its entirety into this application.

### BACKGROUND OF THE INVENTION

1. Technical Field

The present invention relates to a printed circuit board and a method for manufacturing the same, and more particularly, to a printed circuit board provided with an insulating film covering a surface of an insulating layer and a method for manufacturing the same.

2. Description of the Related Art

Generally, a printed circuit board (PCB) is manufactured by attaching a thin plate of copper, and the like, to one surface of a phenol resin insulating plate, an epoxy resin insulating plate, and the like, forming a micro electrode layer, and forming holes in which components are mounted. The printed circuit board serves to hold a plurality of electronic components, electrically connect the mounted electronic components with each other, and insulate adjacent circuits from each other.

Recently, as lightness and slimness of mobile communication devices and electronic products have been quickly progressed, technologies of the printed circuit board have been suddenly developed to be suited for multi-layer, high-density, and multi-functional products. In particular, one of the most important problems in the fields of an audio power module, a power module for PDP, a motor controller, an LED lamp, a light emitting diode backlight unit (LED BLU), a thermoelectric material, a high-output semiconductor device, and the like, is the very heat generation. Therefore, there is a need to adopt an effective heat radiating structure so as to prevent the reliability of products from being degraded.

FIG. 1 is a cross-sectional view showing a flame retardant (FR-4) printed circuit board that is a printed circuit board according to the related art.

As shown, the FR-4 printed circuit board according to the related art has a structure in which an insulating layer 130 is disposed between a base substrate 110 and a copper electrode layer 120. In more detail, the insulating layer 130 is manufactured by impregnating epoxy 131 in a glass fiber 132 that is made by crossing woofs and meridians like weaving cloth. When manufacturing the PCB by making the insulating layer 130 in a sheet shape, a copper clad laminate (CCL) is manufactured by performing vacuum thermal compression on electrolytic copper foils on both surfaces thereof and forming the electrode layer 120 formed with a printed electrode layer based on a photo process. The photo process generally includes processes such as photoresist coating, exposing, etching, photoresist strip, and the like, which are known in PCB industries. Therefore, the processes are referred to below as a photo process.

In the general FR-4 PCB, the insulating layer 130 has a thickness of approximately 75 μm or more and the glass fiber 132 and the epoxy 131 generally have very low thermal conductivity as 0.25 W/mK, such that the FR-4 PCB is not appropriate to be used as the PCB for the LED and the high-output semiconductor device. When the thickness of the insulating layer 130 is reduced, thermal resistance may be reduced even in the case of the same thermal conductivity, but the required dielectric breakdown voltage is reduced. Therefore, there is a limitation in reducing the thickness of the insulating layer 130. Further, since permittivity of the epoxy resin is low, the thick insulating layer needs to be used so as to obtain sufficient insulation property. As the thickness of the insulating layer is thick, the thermal resistance may be suddenly increased and as the epoxy resin has an insufficient adhesion with the base substrate and absorbs moisture well, the reliability of products may be degraded.

In order to increase the thermal conductivity and the dielectric breakdown voltage, metal or alloy with excellent thermal conductivity is generally used as the base substrate and the base substrate of the metal (for example, aluminum) is subjected to anodizing to make an alumina insulating layer. As another structure, Korean Patent Laid-Open Publication No. 10-2010-0099475 (hereinafter, Related Art Document) proposes a substrate that is configured to include a base substrate, a first interface insulating film formed on the base substrate, an insulating layer formed on the first interface insulating film, a second interface insulating film formed on the insulating layer, and an electrode layer formed on the second interface insulating film.

However, when the alumina insulating layer is made by performing the anodizing on the aluminum base substrate, the alumina insulating layer has a porous structure filled with air to cause air spark between the electrode layer and the lower aluminum base substrate, which makes it difficult to secure the high dielectric breakdown voltage. In addition, it takes much process time to grow the insulating layer at a uniform thickness and it is very difficult to secure sufficient insulation property.

Further, in the case of the substrate proposed in the related art document, the interface insulating films should be stacked on both surfaces of the insulating layer and therefore, the number of processes is increased, which leads to the degradation in costs and productivity. Further, the interface film is formed of oxide or nitride and therefore, has many pores like the alumina insulating layer, which makes it difficult to secure the high dielectric breakdown voltage.

### RELATED ART DOCUMENT

### Patent Document

(Patent Document 1) Patent Document: Korean Patent Laid-Open Publication No. 10-2010-0099475

### SUMMARY OF THE INVENTION

An object of the present invention is to provide a printed circuit board capable of securing high dielectric breakdown voltage while keeping high thermal conductivity by covering an insulating film with low air permeability on a surface of an insulating layer, and a method for manufacturing the same.

In accordance with one aspect of the present invention to achieve the object, there is provided A printed circuit board, comprising: a base substrate formed of anodizable metals; an insulating layer formed on one surface or both surfaces of the base substrate; an electrode layer formed on a top surface of the insulating layer; and an insulating film covering a surface of the insulating layer except for a bonding surface between the electrode layer and the insulating layer and having a height equal to or lower than that of the electrode layer.

Further, the insulating layer is formed of metal oxide.

Further, the insulating film has low air permeability.

Further, the insulating film is formed of a photosensitive material.

Further, the electrode layer includes a seed layer and a metal layer formed using the seed layer as a lead-in wire by electroplating, and

the seed layer is disposed on a bottom surface of the metal layer or is disposed on the bottom surface and a side of the metal layer.

In accordance with another aspect of the present invention to achieve the object, there is provided A printed circuit board, comprising: a base substrate; an insulating layer formed on one surface or both surfaces of the base substrate;

an electrode layer formed on a top surface of the insulating layer; and an insulating film covering a surface of the insulating layer except for a bonding surface between the electrode layer and the insulating layer and partially incorporated in the electrode layer.

Further, a bonding length 2L between a top surface of the insulating film and the electrode layer is 0.1 to 0.6 of a width W of the electrode layer.

In accordance with another aspect of the present invention to achieve the object, there is provided A method for manufacturing a printed circuit board, comprising: (a) preparing a base substrate; (b) forming an insulating layer on one surface or both surfaces of the base substrate; (c) forming an insulating film covering a surface of the insulating layer; (d) etching the insulating film in an area of an electrode layer to machine an opening part; and

(e) plating an inner part of the opening part to form the electrode layer.

Further, step (e) includes: plating a metal layer completely covering the insulating film and the opening part; and

etching the metal layer according to a predetermined pattern.

Further, the metal layer is formed by forming the seed layer on a top surface of the insulating film, on a top surface of the insulating layer exposed through the opening part, and in an inner wall of the opening part and electroplating the seed layer as a lead-wire line.

Further, step (e) includes: forming the seed layer on only the top surface of the insulating layer exposed through the opening part; and filling and plating the opening part using the seed layer as a lead-in wire.

Further, a width of the electrode layer formed at step (e) is equal to that of the opening part.

Further, a width of the electrode layer formed at step (e) is larger than that of the opening part.

### BRIEF DESCRIPTION OF THE DRAWINGS

FIG. 1 is a cross-sectional view of a printed circuit board according to the related art.

FIG. 2 is a cross-sectional view of a printed circuit board according to an exemplary embodiment of the present invention.

FIG. 3 is a cross-sectional view of a printed circuit board according to another exemplary embodiment of the present invention.

FIG. 4 is a cross-sectional view of a printed circuit board according to another exemplary embodiment of the present invention.

FIGS. 5 to 9 are views sequentially showing the process of manufacturing a printed circuit board according to the exemplary embodiment of the present invention.

### DESCRIPTION OF THE PREFERRED EMBODIMENTS

Various advantages and features of the present invention and methods accomplishing thereof will become apparent from the following description of embodiments with reference to the accompanying drawings. However, the present invention may be modified in many different forms and it should not be limited to the embodiments set forth herein. These embodiments may be provided so that this disclosure will be thorough and complete, and will fully convey the scope of the invention to those skilled in the art. Like reference numerals throughout the description denote like elements.

Terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

Hereinafter, a configuration and an acting effect of exemplary embodiments of the present invention will be described in more detail with reference to the accompanying drawings.

FIG. 2 is a cross-sectional view of a printed circuit board according to an exemplary embodiment of the present invention.

Referring to FIG. 2, a printed circuit board according to an exemplary embodiment of the present invention may be configured to include a base substrate 210, an insulating layer 220, an insulating film 230, and an electrode layer 240.

The printed circuit board according to the exemplary embodiment of the present invention may be a heat radiating substrate that radiates heat generated from an LED or a high output semiconductor device. Therefore, according to the exemplary embodiment of the present invention, the base substrate 210 may be formed of materials with excellent thermal conductivity and may be formed of any material without being particularly limited.

However, as described below, when the insulating layer 220 is formed by anodizing or plasma electrolytic oxidation treatment, the base substrate 210 needs to be formed of anodizable metals. For example, the base substrate 210 may be preferably formed of metal consisting of at least any one of aluminum (Al), magnesium (Mg), manganese (Mn), zinc (Zn), titanium (Ti), hafnium (Hf), tantalum (Ta), niobium (Nb), and an alloy thereof.

In addition, when the base substrate 210 may be formed of the foregoing metal materials, the base substrate 210 has rigidity larger than a substrate formed of a general resin layer and therefore, has resistance against warpage.

The insulating layer 220 formed on one surface or over the base substrate 210 is a layer that is insulated to prevent the electrode layer 240 and the base substrate 210 from being electrically shorted. The insulating layer 220 may be formed by performing the anodizing or the plasma electrolytic oxidation treatment on the surface of the base substrate 210 of the foregoing metal material in order to implement the higher thermal conductivity.

In this case, the insulating layer 220 is formed of metal oxide. For example, if it is assumed that a material of the base substrate 210 is aluminum (Al), the insulating layer 220 may be formed of alumina Al2O3 formed by anodizing aluminum.

The alumina (Al₂O₃) has excellent insulation property and thermal conductivity, and therefore, exhibits the excellent heat radiating effect while sufficiently securing the insulation property between the base substrate 210 and the electrode layer 240 even though the thickness is thin. Therefore, when the insulating layer 220 is formed of metal oxide, the thickness of the insulating layer 220 may have an appropriate value within the range of several μm to several hundreds of μm according to the usage of the substrate.

Meanwhile, the insulating layer 220 is formed of a glass fiber in which the general epoxy is incorporated, the epoxy resin to which ceramic filler is added, and the like. However, as described above, metal oxides such as alumina (Al₂O₃) has more excellent insulation property and thermal conductivity than resin and the present invention has a characteristic in that the insulating film 230 is formed on the surface of the insulating layer 220 formed of metal oxide and having a porous structure. Therefore, the insulating layer 220 is preferably formed of metal oxide formed by anodizing or plasma electrolytic oxidation treatment.

The electrode layer 240 may be a signal layer that may transfer electrical signals to various elements and may be a pad layer that is directly bonded to semiconductor devices. Alternatively, the electrode layer 240 may be a ground or an electrode layer for a power supply. In the embodiment of FIG. 2, the electrode layer 240 is illustrated as the pad layer, but may be configured as the signal layer or the ground or the electrode layer for the power supply.

Describing in more detail the structure of the electrode layer 240, the electrode layer 240 may be configured to include a seed layer 241 and a metal layer 242, wherein the seed layer 241 and the metal layer 242 may include any one or two selected from a group consisting of nickel, copper, gold, silver, tin, and cobalt that have excellent electric conductivity.

The seed layer 241 is a thin metal film formed on the insulating layer 220 using an electroless plating process or a sputtering process and the metal layer 242 may be formed using the seed layer 241 as a lead-in wire by electroplating. In addition to this, the metal layer 242 may be formed by various plating methods that are known to those skilled in the art and the seed layer 241 may be omitted according to the plating methods.

Further, the seed layer 241 may be formed only on a bottom surface of the metal layer 242 and as shown in FIG. 2, may be formed on a side of the metal layer 242 as well as on the bottom surface thereof, according to a manufacturing method to be described below.

Meanwhile, when the electrode layer 240 is the pad layer, the electrode layer 240 may be wire-boned or soldered to the semiconductor device and the plating layer 243 may be further formed on a top surface and a side of the metal layer 242 so as to prevent the corrosion of the metal layer 242. The plating layer 243 is formed of gold (Au) and generally, is formed using the electroplating method but may be formed using electroless plating methods such as electroless nickel immersion gold (ENIG), electroless nickel autocatalytic gold (ENAG), electroless nickel electroless palladium immersion gold (ENEPIG) methods, and the like.

The insulating film 230 is formed on a top surface of the insulating layer 220 and is covered on the surface of the insulating layer 220, except for a bonding surface between the electrode layer 240 and the insulating layer 220. Therefore, a side of the electrode layer 240 is also covered with the insulating film 230 as much as a thickness height of the insulating film 230. In this case, a height of the insulating film 230 may be formed to be lower than the electrode layer 240 or may be formed to be equal to the electrode layer 240, as shown in FIG. 2.

The insulating film 230 is formed of compositions having small and uniform particles so as to prevent oxygen in the air from permeating the insulating film 230. Therefore, the insulating film 230 may be formed of any materials with low air permeability and excellent insulation property. Further, the insulating layer 230 may be more preferably formed of materials having photosensitivity so as to facilitate patterning by the photo process. For example, the insulating layer 230 may be made of photosensitive polyimide.

When the insulating film 230 of a material having low air permeability is formed to have the foregoing structure, the surface of the insulating layer 220 and a bonding portion A between the electrode layer 240 and the insulating layer 220 are not exposed to the outside due to the insulating film 230. Therefore, even though the insulating layer 220 is formed of metal oxide having a porous structure, the insulating layer 220 does not directly contact oxygen in the air to prevent air spark from occurring between the electrode layer 240 and the base substrate 210, such that the printed circuit board according to the exemplary embodiment of the present invention can secure high dielectric breakdown voltage.

In this case, the thickness of the insulating film 230 may be several nm to several hundreds of μm. When the thickness of the insulating film 230 is too thin, the oxygen in the air may permeate the insulating film 230 to contact the insulating layer 220 and the thickness is not easily controlled and thus, productivity may be degraded. To the contrary, when the thickness of the insulating film 230 is too thick, the thermal conductivity of the overall substrate may be degraded and it may be difficult to implement the light and slim substrate. Therefore, the thickness of the insulating film 230 is preferably formed within an appropriate range.

Hereinafter, a printed circuit board according to another exemplary embodiment of the present invention will be described.

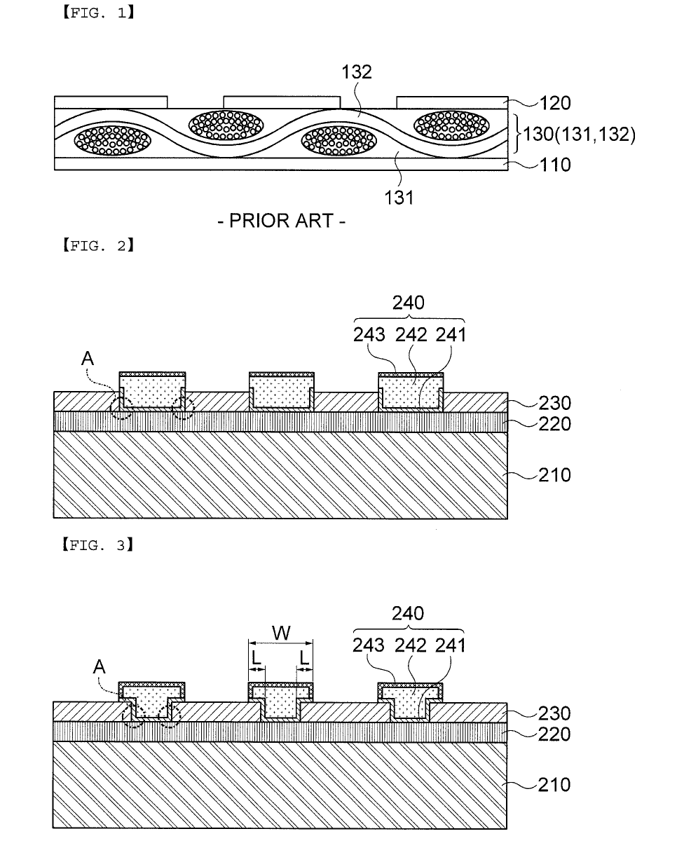

FIG. 3 is a cross-sectional view of a printed circuit board according to another exemplary embodiment of the present invention. Each component in the exemplary embodiment of FIG. 3 is denoted by reference numerals used in FIG. 1.

Referring to FIG. 3, according to another exemplary embodiment of the present invention, the insulating film 230 is formed on the insulating layer 220, but has a structure in which the insulating film 230 is partially incorporated in the electrode layer 240 and covers the surface of the insulating layer 220 except for the bonding surface between the electrode layer 240 and the insulating layer 220. In detail, the insulating film 230 has a structure in which the insulating film 230 is incorporated by a length L from an end of the electrode layer 240. In addition to this, the material and thickness of the insulating film 230 are the same as FIG. 2.

As such, the bonding portion A between the electrode layer 240 and the insulating layer 220 may be more securely shielded with external air due to the structure in which the insulating film 230 is partially incorporated in the electrode layer 240, thereby securing the higher dielectric breakdown voltage.

Further, the electrode layer 240 is bonded to the insulating film 230 by an area corresponding to a bonding length 2L between the top surface of the insulating film 230 and the electrode layer 240. Structurally, the electrode layer 240 is bent so as to be bonded to the insulating film 230, such that the adhesion between the electrode layer 240 and the insulating layer 220 may be more increased.

Meanwhile, the bonding length 2L between the top surface of the insulating film 230 and the electrode layer 240 has a value of 0.1 to 0.6 of a width W of the electrode layer 240. The larger the bonding length 2L between the top surface of the insulating film 230 and the electrode layer 240, the larger the foregoing effects. However, when the bonding length 2L is too larger, an electrical short between the electrode layers may occur.

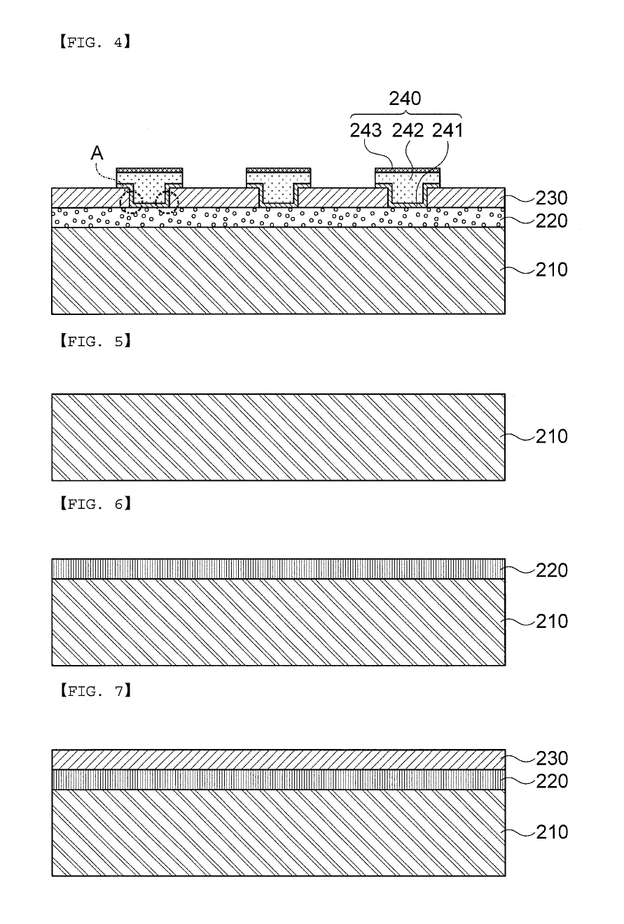

FIG. 4 is a cross-sectional view of a printed circuit board according to another exemplary embodiment of the present invention.

Referring to FIG. 4, according to another exemplary embodiment of the present invention, the insulating layer 220 has a structure in which a composition particle 231 of the insulating film 230 is filled therein.

As described above, when the insulating layer 220 is made of metal oxide according to the anodizing or the plasma electrolytic oxidation treatment, numerous pores are formed in the insulating layer 220. Therefore, as shown in FIG. 4, the composition particle 231 of the insulating film 230 may be filled in the pores of the insulating layer 220 during the process of applying the insulating film 230 to the surface of the insulating layer 220.

As such, when the pores of the insulating layer 220 are sealed by the composition particle 231 of the insulating film 230, the air spark does not occur between the electrode layer 240 and the base substrate 210 to secure the higher dielectric breakdown voltage.

Hereinafter, a method for manufacturing a printed circuit board according to an exemplary embodiment of the present invention will be described with reference to FIGS. 5 to 9.

FIGS. 5 to 9 are views sequentially showing the process of manufacturing a printed circuit board according to the exemplary embodiment of the present invention. First, as shown in FIG. 5, a step of preparing the base substrate 210 is performed.

The material forming the base substrate 210 is not particularly limited, but as in processes to be described below, when the base substrate 210 is subjected to the anodizing or the plasma electrolytic oxidation treatment to form the insulating layer, the base substrate 210 preferably includes anodizable metals.

Next, as shown in FIG. 6, a step of forming the insulating layer 220 on one surface or both surfaces of the base substrate 210 is performed.

The insulating layer 220 may also be formed by bonding a sheet in which the epoxy is incorporated in the glass fiber or an epoxy sheet to which the ceramic filler is added, but is preferably formed by performing the anodizing or the plasma electrolytic oxidation treatment on the base substrate 210 of a metal material, in terms of the thermal conductivity.

Describing in more detail the process of forming the insulating layer 220, the insulating layer 220 formed of the metal oxide may be formed on the surface of the base substrate 210 by dipping the base substrate 210 in an acidic solution (electrolyte solution) while connecting to an anode of a DC power supply.

For example, when the base substrate 210 is formed of aluminum, aluminum ions (Al³⁺) are formed on the surface of the base substrate 210 at the time of the reaction of the surface of the base substrate 210 with the electrolyte solution. In this case, current density is concentrated on the substrate of the base substrate 210 due to voltage applied to the base substrate 210 to locally generate heat and more aluminum ions (Al³⁺) are formed due to the heat. As a result, a plurality of grooves are formed on the surface of the base substrate 210 and oxygen ions (O²⁻) move to the grooves due to a force of electric field to react with the aluminum ions (Al³⁺), such that the insulating layer 220 formed of alumina (Al₂O₃) can be formed.

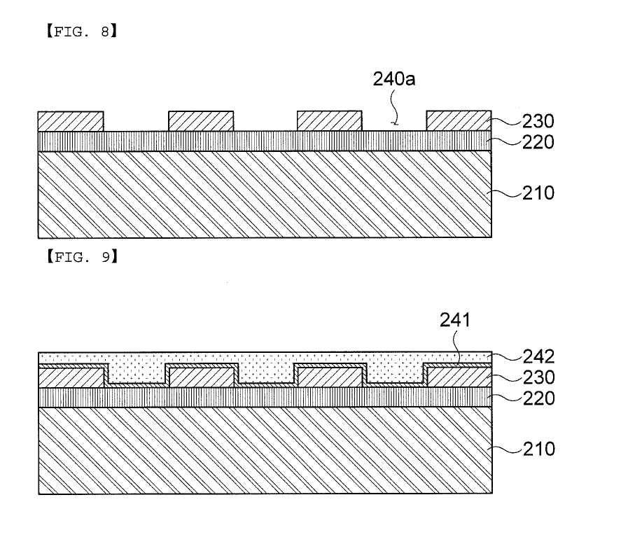

When the insulating layer 220 is formed according to the method, as shown in FIG. 7, a step of forming the insulating film 230 completely covering the surface of the insulating layer 220 exposed to the outside is performed.

The insulating film 230 is preferably formed of a photosensitive material so as to machine the subsequently performed opening part 240a, for example, may be formed of photosensitive polyimide.

The method for forming the insulating film 230 may be a method known to those skilled in the art. For example, when an evaporation method or methods such as solvent process, and the like, can be applied, an example of the solvent process may include spin coating, dip coating, doctor blading, screen printing, inkjet printing, thermal transfer, and the like.

Next, as shown in FIG. 8, a step of forming the opening part 240a by etching the insulating film 230 in the area of the electrode layer 240 is performed.

The opening part 240a may be formed by the photo process. Describing in more detail this, first, a predetermined pattern of mask (not shown) is attached on the insulating film 230. When the top surface of the insulating film 230 is exposed with ultraviolet rays and developed in the state in which the mask is attached thereto, a portion irradiated with ultraviolet rays is cured and remains as it is and a portion that is not irradiated with ultraviolet rays while being covered with the mask is removed without being cured to form the opening part 240a at a desired position.

Next, a step of forming the electrode layer 240 by performing the plating treatment around the area of the opening part 240a is performed.

The electrode layer 240 may be formed by forming the seed layer only on the top surface of the insulating layer 220 exposed through the opening part 240a by the sputtering and filling and plating the formed seed layer as the lead-in wire in the opening part 240a.

As another method, as shown in FIG. 9, the metal layer 242 completely covering the top surface of the substrate is formed and then, the metal layer 242 may be etched and formed according to a predetermined pattern. The metal layer 242 may be formed by the electroplating. To this end, the seed layer 241 may be formed on the top surface of the insulating film 230, the top surface of the insulating layer 220 exposed through the opening part 240a, and an inner wall of the opening part 240a by the electroless plating process or the sputtering process. In this case, the seed layer 241 may be formed at a thickness suitable to perform the electroless plating.

When the seed layer 241 and the metal layer 242 are formed, the metal layer 242 is patterned by the general photo process including photo resist coating, exposing, developing, etching, photoresist strip, and the like, to form a desired pattern of electrode layer 240.

In this case, when the width of the electrode layer formed by the patterning is formed to be equal to the width of the opening part 240a, it has the same structure as the exemplary embodiment of FIG. 2 and when the width of the electrode layer formed by the patterning is formed to be larger than that of the opening part 240a, it has the same structure as the exemplary embodiment of FIG. 3.

According to the printed circuit board and the method for manufacturing the same in accordance with the exemplary embodiments of the present invention, it is possible to secure the high dielectric breakdown voltage while keeping the high thermal conductivity and increase the adhesion between the insulating layer and the electrode layer.

Further, it is possible to increase the thermal conductivity and the dielectric breakdown voltage with the simpler process, without the complicated processes as in the related art, thereby reducing the manufacturing costs and improving the productivity.

The above detailed description exemplifies the present invention. Further, the above contents just illustrate and describe preferred embodiments of the present invention and the present invention can be used under various combinations, changes, and environments. That is, it will be appreciated by those skilled in the art that substitutions, modifications and changes may be made in these embodiments without departing from the principles and spirit of the general inventive concept, the scope of which is defined in the appended claims and their equivalents. Although the exemplary embodiments of the present invention have been disclosed for illustrative purposes, those skilled in the art will appreciate that various modifications, additions and substitutions are possible, without departing from the scope and spirit of the invention as disclosed in the accompanying claims. Therefore, the detailed description of the present invention does not intend to limit the present invention to the disclosed embodiments. Further, it should be appreciated that the appended claims include even another embodiment.

1. A printed circuit board, comprising:
a base substrate formed of anodizable metals;
an insulating layer formed on one surface or both surfaces of the base substrate;
an electrode layer formed on a top surface of the insulating layer; and
an insulating film covering a surface of the insulating layer except for a bonding surface between the electrode layer and the insulating layer and having a height equal to or lower than that of the electrode layer.

2. The printed circuit board according to claim 1, wherein the insulating layer is formed of metal oxide.

3. The printed circuit board according to claim 1, wherein the insulating film has low air permeability.

4. The printed circuit board according to claim 1, wherein the insulating film is formed of a photosensitive material.

5. The printed circuit board according to claim 1, wherein the electrode layer includes a seed layer and a metal layer formed using the seed layer as a lead-in wire by electroplating, and
the seed layer is disposed on a bottom surface of the metal layer or is disposed on the bottom surface and a side of the metal layer.

6. A printed circuit board, comprising:
a base substrate;
an insulating layer formed on one surface or both surfaces of the base substrate;
an electrode layer formed on a top surface of the insulating layer; and
an insulating film covering a surface of the insulating layer except for a bonding surface between the electrode layer and the insulating layer and partially incorporated in the electrode layer.

7. The printed circuit board according to claim 6, wherein a bonding length 2L between a top surface of the insulating film and the electrode layer is 0.1 to 0.6 of a width W of the electrode layer.

8. A method for manufacturing a printed circuit board, comprising:
preparing a base substrate;
forming an insulating layer on one surface or both surfaces of the base substrate;
forming an insulating film covering a surface of the insulating layer;
etching the insulating film in an area of an electrode layer to machine an opening part; and
plating an inner part of the opening part to form the electrode layer.

9. The method according to claim 8, wherein the plating includes: plating a metal layer completely covering the insulating film and the opening part; and
etching the metal layer according to a predetermined pattern.

10. The method according to claim 9, wherein the metal layer is formed by forming the seed layer on a top surface of the insulating film, on a top surface of the insulating layer exposed through the opening part, and in an inner wall of the opening part and electroplating the seed layer as a lead-wire line.

11. The method according to claim 8, wherein the plating includes:
forming the seed layer on only the top surface of the insulating layer exposed through the opening part; and
filling and plating the opening part using the seed layer as a lead-in wire.

12. The method according to claim 8, wherein a width of the electrode layer formed at the plating is equal to that of the opening part.

13. The method according to claim 8, wherein a width of the electrode layer formed at the plating is larger than that of the opening part.
